(19) United States
(12) Patent Application Publication
(10) Pub. No.: US 2014/0167815 A1
(43) Pub. Date: Jun. 19, 2014

(54) AREA RECONFIGURABLE CELLS OF A STANDARD CELL LIBRARY

(71) Applicant: BROADCOM CORPORATION, Irvine, CA (US)

(72) Inventor: Paul PENZES, Irvine, CA (US)

(73) Assignee: BROADCOM CORPORATION, Irvine, CA (US)

(21) Appl. No.: 13/719,188

(22) Filed: Dec. 18, 2012

(51) Int. Cl. H03K 19/177; G06F 17/50; H01L 21/82

(52) U.S. Cl. CPC H03K 19/17748; H01L 21/82; G06F 17/5072
USPC 326/41; 438/129; 716/119

(57) ABSTRACT

An integrated circuit using area reconfigurable cells of a standard cell library includes standard cells placed adjacent with one another in rows and columns. Each of the standard cells has a boundary type and each has a body having a first pair of opposite sides and a second pair of opposite sides orthogonal to the first pair of opposite sides. Each standard cell also has a spacer located adjacent to each of the first pair of opposite sides of the body. The spacer has a spacer type that corresponds to the boundary type of the standard cell. The spacer is removable from the standard cell when the spacer has a spacer type that matches another spacer of an adjacent standard cell.

### BACKGROUND

Standard cells contain a N-transistor pull-down (“NP”) and a P-transistor pull-up (“PP”). The P-transistor is formed in an N-type well (“NWELL”) whereas the N-transistor is formed on a P-type substrate. Depending on the logic function being implemented, there exists a timing optimal ratio of the P-transistor to the N-transistor. For example, when the logic function is an inverter gate, the P-transistor needs to be sized √μ times larger than the N-transistor, where μ is the relative mobility of holes over electrons. Similarly, for a two-way NAND gate, the P-transistor needs to be sized √(μ/2) times larger than the N-transistor. Because larger-sized transistors require a greater share of the standard cell area, standard cells having different sizing ratios provide different edge positions at their boundaries.

Since standard cells are designed to provide geometric regularity, they require abutment with each other in the same orientation according to design-rule restrictions. This then forces an edge of an active device (e.g., NWELL/PP/NP) to be designed in a same location for each standard cell so adjacent cells can align properly. However, this edge alignment reduces the flexibility to size the P-transistor relative to the N-transistor, thus resulting in sub-optimal delay characteristics.

### SUMMARY

A circuit and/or method is provided for area reconfigurable cells of a standard cell library, substantially as illustrated by and/or described in connection with at least one of the figures, as set forth more completely in the claims.

### BRIEF DESCRIPTION OF THE DRAWINGS

Certain features of the subject disclosure are set forth in the appended claims. However, for purpose of explanation, several implementations of the subject disclosure are set forth in the following figures.

FIG. 1 illustrates a high-level environment used in the design of integrated circuits in accordance with one or more implementations.

FIG. 2 illustrates an integrated circuit in accordance with one or more implementations.

FIG. 3 illustrates a perspective view of a fin-based multi-gate transistor for use in a standard cell illustrated in FIG. 2 in accordance with one or more implementations.

FIG. 4 illustrates a standard cell 400 with spacers in accordance with one or more implementations.

FIG. 5 illustrates a flow diagram of a method for area reconfiguration of standard cells of a standard cell library in accordance with one or more implementations.

FIG. 6 illustrates a conceptual diagram of adjacent standard cells with varying edges separated by corresponding spacers in accordance with one or more implementations.

FIG. 7 illustrates a conceptual diagram of spacers of varying edges in accordance with one or more implementations.

FIG. 8 illustrates a conceptual diagram of an optimization of adjacent standard cells with corresponding spacers of a matching spacer type in accordance with one or more implementations.

FIG. 9 illustrates a conceptual diagram of adjacent standard cells with varying spacer types in accordance with one or more implementations.

FIG. 10 conceptually illustrates an electronic system in accordance with one or more implementations.

### DETAILED DESCRIPTION

It is understood that other configurations of the subject disclosure will become readily apparent to those skilled in the art from the following detailed description, wherein various configurations of the subject disclosure are shown and described by way of illustration. As will be realized, the subject disclosure is capable of other and different configurations and its several details are capable of modification in various other respects, all without departing from the scope of the subject disclosure. Accordingly, the drawings and detailed description are to be regarded as illustrative in nature and not as restrictive.

The subject technology addresses the aforementioned limitations with respect to quantification restrictions in circuit design processes by proposing a standard cell library for designing an integrated circuit, in which the standard cell library includes standard cells that are composed of transistor devices and include spacers located on at least opposite sides of each standard cell, and are capable of being removed from the standard cell to reconfigure the size of the integrated circuit. The spacers provide a buffer between neighboring standard cells having varying boundaries (e.g., different NWELL/PP/NP edges). In this regard, the area between the neighboring standard cells can be optimized by determining whether the spacers located at the boundaries between adjacent standard cells are removable to absorb the area used by the spacers, and thereby obtain optimal delay characteristics between the adjacent standard cells.

According to some implementations, an integrated circuit using area reconfigurable cells of a standard cell library includes standard cells placed adjacent with one another in rows and columns. Each of the standard cells has a boundary type and each has a body having a first pair of opposite sides and a second pair of opposite sides orthogonal to the first pair of opposite sides. Each standard cell also has a spacer located adjacent to each of the first pair of opposite sides of the body. The spacer has a spacer type that corresponds to the boundary type of the standard cell. The spacer is removable from the standard cell when the spacer has a spacer type that matches another spacer of an adjacent standard cell.

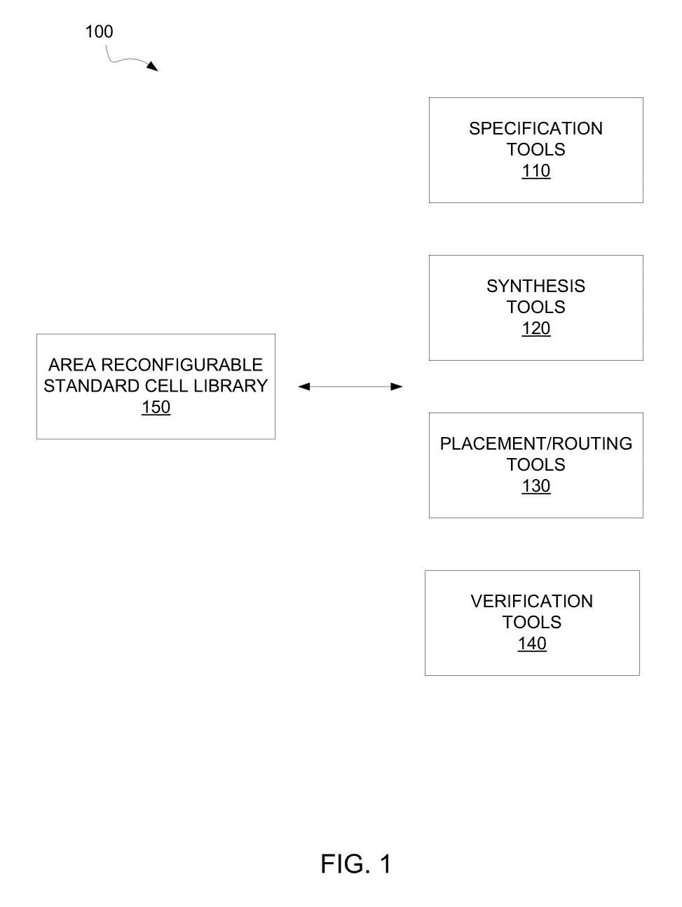

FIG. 1 illustrates a design environment 100 used in the design of integrated circuits in accordance with one or more implementations. The design environment 100 includes specification tools 110, synthesis tools 120, placement/routing tools 130, and verification tools 140. During the design process, the functionality of the chip is specified in a specification tool 110 using a standard hardware programming language such as Verilog. The resulting circuit description is synthesized/mapped into the basic gates of an area reconfigurable standard cell library 150, using one or more synthesis tools 120. The resulting gate netlist is then placed and routed using placement/routing tools 130. Finally, the connectivity and functionality of the integrated circuit are verified using a verification tool 140.

While each of these components is important for the final quality of the resulting integrated circuit, the quality of implementation achievable by most of these components is design dependent. For example, a good Verilog code specifying circuit A, does not make an independent circuit B any better. However, an adequate standard cell library makes all designs better. The quality of the standard cell library influences all designs and as such has a far reaching influence on the quality of the resulting integrated circuit chip.

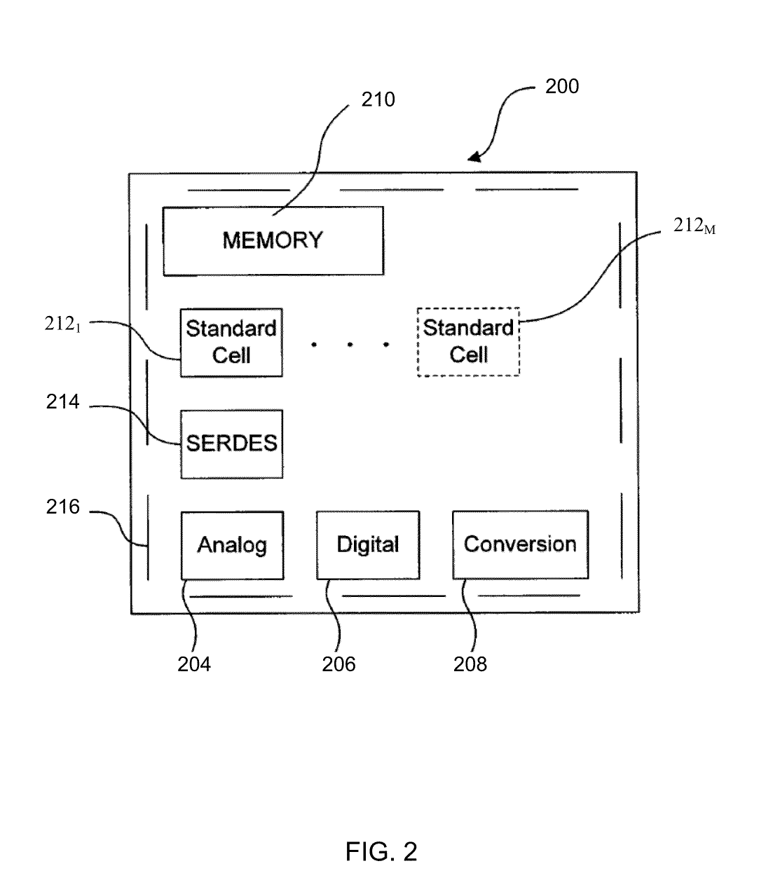

FIG. 2 illustrates an integrated circuit 200 in accordance with one or more implementations. The integrated circuit 200 includes an analog portion 204, a digital portion 206, a conversion portion 208 (e.g., analog-to-digital and/or digital-to-analog conversions), a memory 210, and standard cells 212₁-212_{M}. Optionally, the integrated circuit 200 includes a SERDES portion 214, which is a serial-deserializer device that converts input serial data to deserialized parallel data for use by the other portions of integrated circuit 200.

According to some implementations, elements 204-214 can be proprietary or manufacturer specific, with the normal exception of the standard cells 212₁-212_{M}. The standard cells 212₁-212_{M} can vary in size based on a size and/or number of devices thereon, e.g., a size of logic devices (sometimes referred to as gates, and used interchangeably below) thereon or a number of logic devices thereon, to provide an optimal combination of size, signal propagation speed, or leakage. Each of the standard cells 212₁-212_{M} is designed to perform a specific function or set of functions or processes on a propagating signal. These functions are represented by combination of transistors forming various logic gates, as discussed in more detail below.

The area reconfigurable standard cell library 150 (FIG. 1) may include hundreds of standard cells, where the standard cells 212₁-212_{M} are a subset of the area reconfigurable standard cell library 150 and are selectively combined to design a larger circuit. Each of the standard cells 212₁-212_{M} in the library is associated with a specific logic function. Each logic function may be implemented in one or more predefined cells. For example, a logic function may have multiple layouts, each having different characteristics (e.g., timing characteristics).

Each of the standard cells 212₁-212_{M} in the area reconfigurable standard cell library 150 can be laid out relative to a grid defined by horizontal and vertical tracks. According to some implementations, the number of horizontal tracks defines the height of the cell and the number of vertical tracks defines the width of the cell. The area reconfigurable standard cell library 150 can be generally classified by its track height. For example, a 10-track library is composed of cells having heights of 10 horizontal tracks (or an integer multiple thereof). The widths of cells in a library may also vary. As such, the track height may be determined based on a desired amount of active area, clearance area, design rule check (DRC) constraints and performance requirements. Standard cells that have different track heights may not be combined by abutting their respective power and ground rails because of the difference in alignment. The standard cells 212₁-212_{M} may have the same track height (or integer multiple of that height).

The type and number of cells added to the area reconfigurable standard cell library 150 is dependent upon the efficiency required for the synthesis tool or application. Adding too many cells to the area reconfigurable standard cell library 150 may significantly reduce the efficiency of the synthesis tool and the quality of the resulting integrated circuit. This is because the synthesis tool may have difficulty handling a large number of choices. Accordingly, multi-threshold voltage cells may only be provided for the most used logic functions. Commonly used functions include, but are not limited to, AND gates, NAND gates, inverters, OR gates, NOR gates, and flip flops. The type of logic function implemented may be arbitrary or design dependent. As design tools become more sophisticated, the area reconfigurable standard cell library 150 can be further extended to include more complex combinational logic cells for a majority or all supported logic functions.

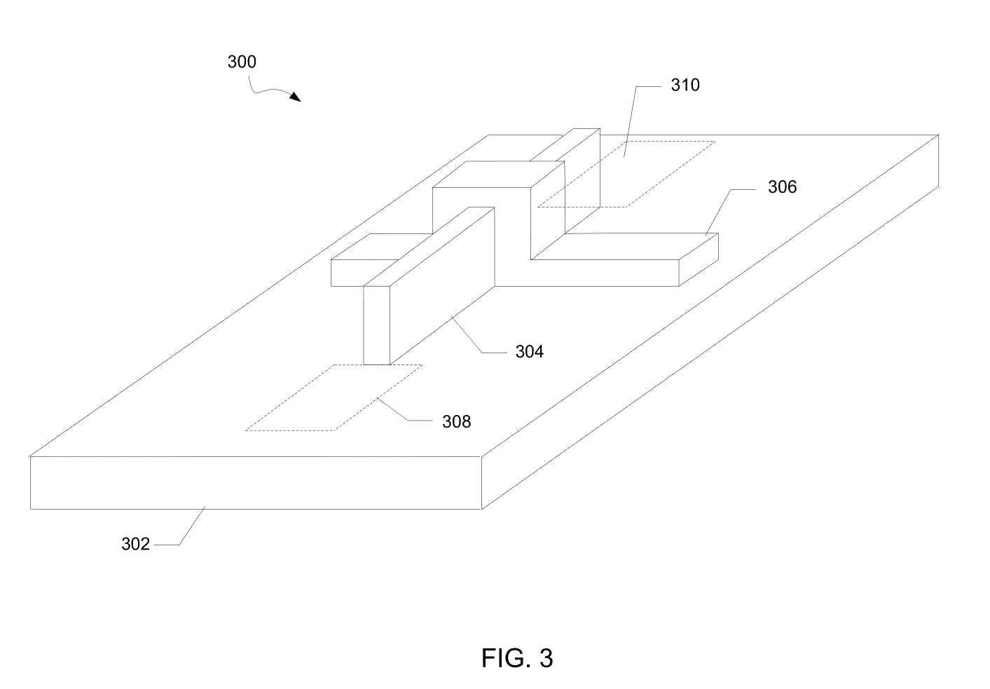

FIG. 3 illustrates a perspective view of a fin-based multi-gate transistor 300 for use in the standard cell illustrated in FIG. 2 in accordance with one or more implementations. The fin-based multi-gate transistor 300 includes a non-conductive substrate 302 supporting a diffusion fin or a semiconductor fin 304. A gate structure 306 is deposited over a portion of the semiconductor fin 304 to form a gated channel between a source 308 and a drain 310. In effect, the gate structure 306 straddles the semiconductor fin 304. During operation, current flows between the source 308 and the drain 310 along the gated sidewall surfaces of the semiconductor fin 304.

According to some implementations, the gate structure 306 is formed using a polysilicon material or a metal. The fin-based multi-gate transistor 300 may be applicable to various technologies, including but not limited to, complementary metal-oxide-semiconductor (CMOS), silicon-on-insulator (SOI), Gallium-Arsenide (GaAs), and Silicon-Germanium (SiGe). In addition, the fin-based multi-gate transistor 300 may be applicable to double-gate transistors, tri-gate transistors, all-around-gate transistors, and various other implementations of semiconductor devices with quantification.

According to some implementations, an integrated circuit is formed using multiple semiconductor fins along an axis that is orthogonal with gate structures (or polysilicon layers) running parallel to one another across the integrated circuit. The intersection of the semiconductor fin 304 and the gate structure 306 over an active material deposited on the substrate 302 forms a transistor. As such, the integrated circuit can be arranged as a grid where multiple grid points represent this intersection. Accordingly, each transistor can be located at a corresponding grid point of the integrated circuit based on the spatial relationship between the semiconductor fin 304 and the gate structure 306. The spacing between the multiple semiconductor fins defines a fin pitch. Similarly, the spacing between the gate structures defines a gate pitch. The fin-based multi-gate transistor 300 is not limited to the implementation shown in FIG. 3, and can be implemented with various configurations and structures.

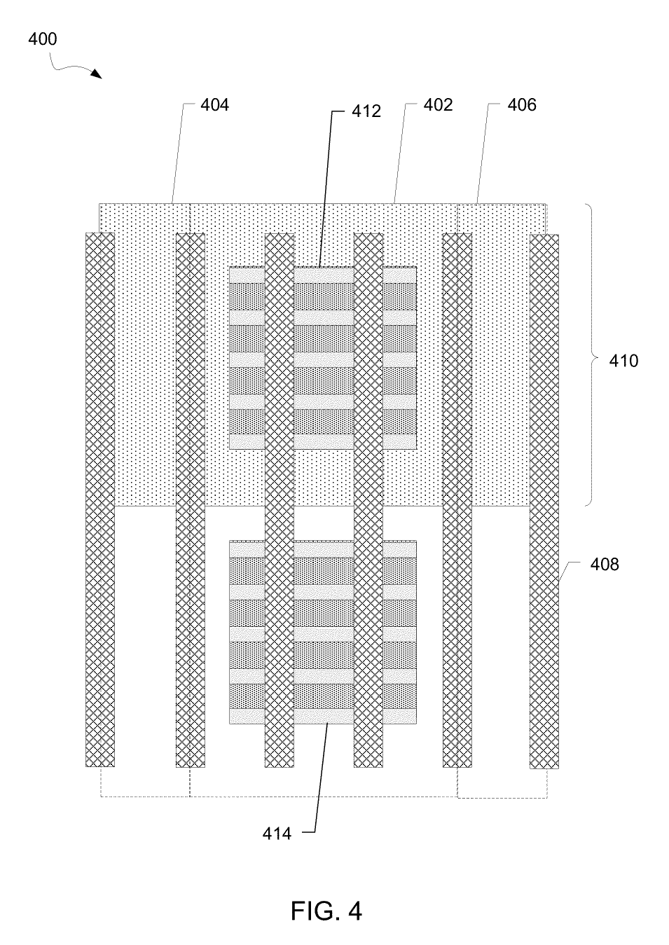

FIG. 4 illustrates a standard cell 400 with spacers in accordance with one or more implementations. According to some implementations, the area reconfigurable standard cell library 150 (FIG. 1) for designing an integrated circuit includes the standard cell 400 with a set of spacers. Particularly, the standard cell 400 includes a body 402 and spacers 404 and 406 located on opposite sides of the body 402. The standard cell has four sides, two of which are parallel to power/ground rails in an integrated circuit. The spacers are formed on the sides of the standard cell that are orthogonal with the power/ground rails.

The standard cell 400 can have transistors of different types. For example, the standard cell 400 can have p-type transistors 412 and n-type transistors 414. According to some implementations, the transistors are fin-shaped field-effect-transistors (finFETs). In this regard, the finFETs provide for a polysilicon 408 (or gate structures) to intersect with semiconductor fins over an N-WELL portion 410 to form the p-type transistors 412. Similarly, the polysilicon 408 intersects with the semiconductor fins over another active material (e.g., P-WELL) to form the n-type transistors 414. As such, the body 402 of the standard cell 400 is composed of p-type transistors 412 and n-type transistors 414.

The spacers 404 and 406 can each be removed from the standard cell 400 when the spacer has a matching spacer type as a spacer of an adjacent standard cell (not shown). The spacer type corresponds to a boundary type of the standard cell 400. The boundary type is defined as an edge position between the different transistor types in the body 402. Here, the edge position is described as the boundary between the p-type transistors 412 and n-type transistors 414. As such, the spacers 404 and 406 are formed with the same edge position as the body 402 so the spacers 404 and 406 along with the body 402 are uniform within the standard cell 400. Because standard cells can have different transistor sizes, the edge position will vary between the standard cells. As such, the spacers 404 and 406 allow adjacent standard cells with varying edge positions to remain adjacent without violating any design rules.

In one or more implementations, the spacer type is identified using an integer value to denote the transistor sizing of one of the transistor types. For example, the standard cell 400 has p-type transistors of size five and n-type transistors of size five, thus the transistor size for either type is five. Hence, the spacer type can be defined with by the integer value of five when the spacers 404 and 406 are being matched with spacers of adjacent standard cells. In this regard, if spacers of adjacent standard cells each have a spacer type of five, then the spacers can be removed from their respective standard cell, thus providing for dynamic area optimization within the integrated circuit.

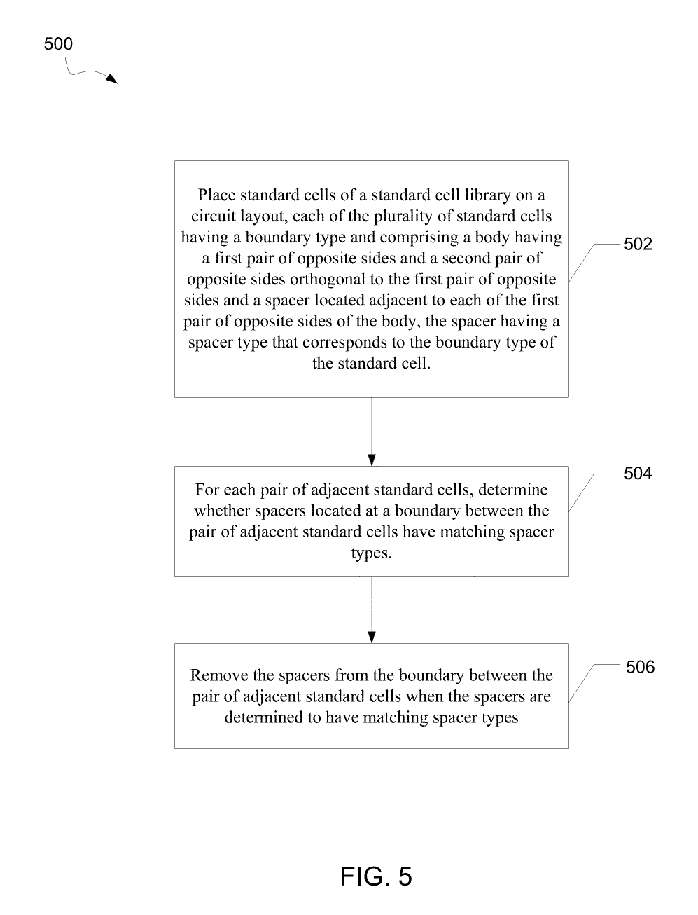

FIG. 5 illustrates a flow diagram of a method 500 for area reconfiguration of standard cells using the area reconfigurable standard cell library 150 (FIG. 1) in accordance with one or more implementations. According to some implementations, the method 500 is not limited to the order illustrated in FIG. 5, and can be performed, executed or processed in a different order capable of optimizing that area of standard cells having fin-based multi-gate transistors. Referring to FIG. 5, the method 500 is performed to form an integrated circuit using the area reconfigurable standard cell library 150.

The method 500 includes placing a plurality of standard cells of the area reconfigurable standard cell library 150 on a circuit layout (502). Each of the standard cells has a boundary type and includes a body having a first pair of opposite sides and a second pair of opposite sides orthogonal to the first pair of opposite sides and a spacer located adjacent to each of the first pair of opposite sides of the body. The spacer has a spacer type that corresponds to the boundary type of the standard cell. In one or more implementations, the standard cells may have different boundary types.

In placing the standard cells, the method 500 also may include arranging the standard cells as an array with the set of spacers separating the standard cell from neighboring standard cells along a row. The method 500 also may include selecting the standard cells from the area reconfigurable standard cell library 150 for placement. The method 500 also may include routing the placed standard cells to determine speed/leakage requirements of the integrated circuit. Once placed and routed, the standard cells may be reconfigured in area by determining which standard cells can have their spacers removed to recover the area.

The method 500 may include identifying a pair of adjacent standard cells with a spacer of each identified standard cell located at a boundary between the pair of adjacent standard cells. The method 500 also includes for each pair of adjacent standard cells, determining whether spacers located at a boundary between the pair of adjacent standard cells have matching spacer types (504). In determining whether the spacers have a matching spacer type, the method 500 also may include determining whether the pair of adjacent standard cells have edge positions that align properly. The determining of the matching spacer type also may include detecting a spacer type of each spacer located between a pair of adjacent standard cells. In detecting the spacer type, the method 500 also may include comparing the spacer type of each spacer to determine a match.

The standard cells use fin-shaped field-effect-transistors (finFETs) to form the integrated circuit. Because of the quantifiable nature of a finFET process, for example, the adjoining sides can be aligned with granularity. The method 500 also may include evaluating an edge position of each spacer to determine a quantifiable difference based on a number of semiconductor fins. If there is a match between the edge positions, the spacers are determined to have a matching spacer type, and therefore removable. If there is no match, then the spacers have different spacer types and will remain placed between the adjacent standard cells to prevent any design-rule violations. The quantifiable difference may correspond to a fin pitch. The fin pitch is defined by the spacing between the semiconductor fins.

In aligning the adjacent standard cells, the method 500 also may include determining whether adjoining sides of the spacers at the boundary between the adjacent standard cells differ by an integer multiple of the quantifiable difference. For example, the spacers may differ by multiple semiconductor fins, and thus the integer multiple can correspond to the number of semiconductor fins. In this regard, adjacent standard cells having a difference in edge positions by two semiconductor fins can be defined as having a quantifiable difference of two. In also aligning the adjacent standard cells, the method 500 may include determining that the spacers at the boundary between the adjacent standard cells have the matching spacer type when the adjoining sides of the spacers have no quantifiable difference.

The method 500 also includes removing the spacers from the boundary between the pair of adjacent standard cells when the spacers are determined to have matching spacer types (506). After removing each of the spacers at the boundary, the method 500 also may include placing decoupling capacitors to the circuit layout at the boundary between the pair of adjacent standard cells. The removed spacer area can be filled with decoupling capacitance, which improves DC voltage drop (e.g., IR drop), and thereby increasing the integrated circuit's speed of operation (e.g., reducing propagation time across the circuit).

The method 500 also may include abutting the pair of adjacent standard cells directly with one another when the spacers having matching spacer types are removed from respective ones of the pair of adjacent standard cells. To do so, the adjoining sides of the spacers should be determined to have no quantifiable difference (or matching spacer type). In this regard, the spacers are removable to allow the adjacent standard cells to abut directly or allow decoupling capacitors to take up the removed spacer space.

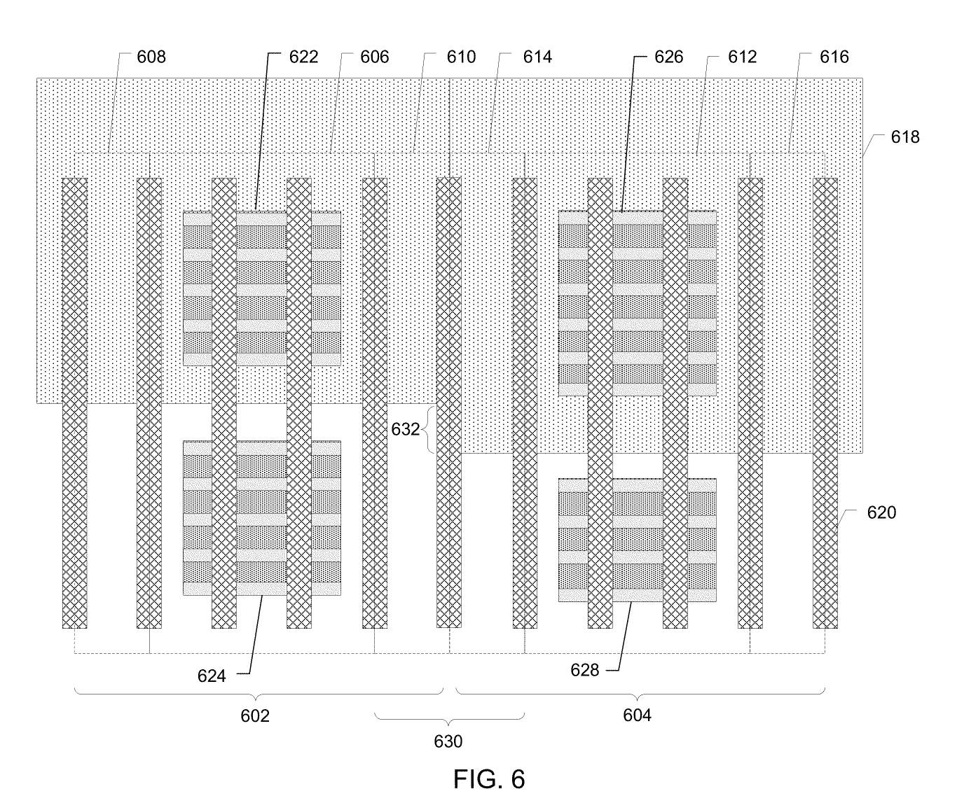

FIG. 6 illustrates a conceptual diagram of adjacent standard cells 602 and 604 with varying edges separated by corresponding spacers in accordance with one or more implementations. According to some implementations, the area reconfigurable standard cell library 150 for designing an integrated circuit includes the standard cells 602 and 604 having different boundary types and each of the standard cells 602 and 604 also including a set of spacers of a spacer type that corresponds to a boundary type of the standard cell and are located on at least opposite sides of the standard cell. For example, the standard cell 602 includes a body 606 and spacers 608 and 610, and the standard cell 604 includes a body 612 and spacers 614 and 616.

According to some implementations, at least one of the set of spacers (e.g., spacer 610) can be removable from a respective one of adjacent standard cells (e.g., standard cell 602) when the at least one of the set of spacers (e.g., spacer 610) has a matching spacer type as a spacer of the adjacent standard cell. Here, the spacer 610 has a spacer type that is different than the spacer 614 of the standard cell 604, which is adjacent to the standard cell 602. Thus, the spacers 610 and 614 are not removed. However, the spacer 610 can be removed if the spacer 614 is aligned properly with the spacer 610 to denote that the two spacers have no quantifiable difference, and thus can be removed from their respective standard cell. In addition, the spacers 608, 610, 614 and 616 can abut other spacers since there are no active devices (or transistors) within them.

The standard cells 602 and 604 each have transistors of different types. According to some implementations, the transistors are based on fin-shaped field-effect-transistors (finFETs). In this regard, the finFETs provide for polysilicon layers 620 (or gate structures) intersect with semiconductor fins over an N-WELL portion 618 to form p-type transistors. In addition, the polysilicon layers 620 intersect with the semiconductor fins over another active material (e.g., P-WELL) to form n-type transistors. As such, the body 606 of the standard cell 602 is composed of p-type transistors 622 and n-type transistors 624, whereas the body 612 of the standard cell 604 is composed of p-type transistors 626 and n-type transistors 628.

A quantifiable difference between N-WELL portion 618 of each corresponding standard cell can be a function of the number of semiconductor fins. In this regard, an N-WELL notch 632 corresponding to the standard cell 604 represents the quantifiable difference between the spacers 610 and 614. Here, the N-WELL notch 632 is approximately the fin pitch involving one semiconductor fin (or a first integer multiple of the fin pitch). The N-WELL notch 632 is far enough from the NP/PP regions of the neighboring standard cell (e.g., standard cell 602) to not cause design-rule violations.

The spacers 608, 610, 614 and 616 can be described according to a spacer type that corresponds to an edge position of the corresponding standard cell. That is, the spacer type is defined according to a quantification of the transistor sizing ratio of the standard cell. In a fin-shaped field effect transistor (or finFET) process, the transistor sizing is measured by a number of fins employed for a corresponding transistor. As such, the greater the number of fins employed, the larger the width of the transistor. Therefore, the edge position can be measured with granularity according to the number of fins employed for each corresponding transistor sizing.

The edge position can also correspond to an active material in the standard cell. Here, the standard cells 602 and 604 have different edge positions because the p-type transistors 622 and 626 have different sizings. Similarly, the n-type transistors 624 and 628 have different transistor sizings. For example, the standard cell 602 has a transistor ratio (e.g., p-type transistors to n-type transistors) of 1:1, whereas the standard cell 604 has a higher transistor ratio (e.g., 3:2) since the p-type transistor 626 has two more semiconductor fins than the n-type transistor 628. As a result, the standard cell 604 has a different boundary type than the standard cell 602. This can be shown by the edge position corresponding to the N-WELL portion 618.

To accommodate the different boundary types between the standard cells 602 and 602, the spacers 610 and 614 can abut at a region 630 of the integrated circuit to provide proper buffering between the NP/PP regions of the standard cells 602 and 604. The spacers 610 and 614 are configured to match the boundary type of the corresponding standard cell since the spacers are abutting directly to the standard cell. As such, the spacer 610 has no quantifiable difference from the standard cell 602, and the spacer 614 has no quantifiable difference from the standard cell 604 so the spacers can align properly to their respective standard cells. As stated above, the standard cells 602 and 604 have different boundary types, hence the spacers 610 and 614 have different spacer types. Alternatively, if the standard cells 602 and 604 have equivalent boundary types, the spacers can have equivalent spacer types since the spacers correspond to their standard cells.

According to some implementations, the standard cells are configured to abut directly with one another when respective ones of the adjacent standard cells have spacers of the matching spacer type located between the adjacent standard cells removed. As such, the adjacent standard cells can decrease in area proportionate to the removed spacers having the matching spacer type. Alternatively, the standard cells can be configured to have decoupling capacitors provided in between adjacent standard cells when spacers having the matching spacer type located between the adjacent standard cells are removed from their respective standard cells.

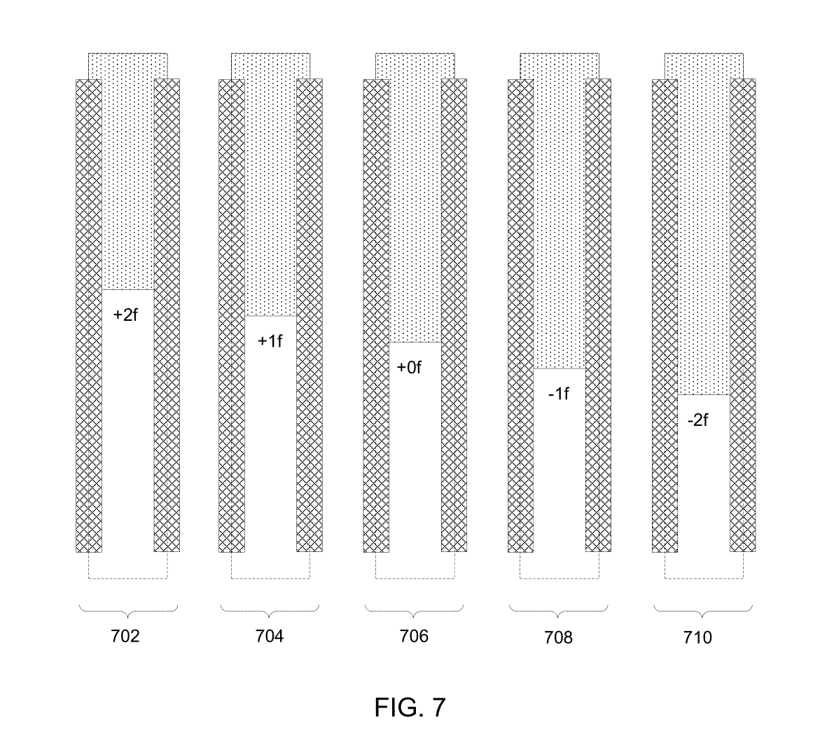

FIG. 7 illustrates a conceptual diagram of spacers 702-610 with varying spacer types in accordance with one or more implementations. As stated above, the area reconfigurable standard cell library 150 provides standard cells that are composed of finFETs (or multi-gate transistors). Because the finFET process is quantifiable, the difference in the number of semiconductor fins used between adjacent standard cells is also quantifiable. For example, a p-type transistor that requires two fins more than the n-type transistor causes the edge position of the standard cell to shift by a delta of two (e.g., −20 when compared to a base case (e.g., both the p-type transistor and the n-type transistor are equally sized for a delta of zero). Similarly, an n-type transistor that requires two fins more than the p-type transistor causes the edge position to shift in the opposite direction by a delta of two (e.g., +20 compared to the base case. In addition, adjacent standard cells with equivalent delta values (e.g., no quantifiable difference) are seen to have spacers of a matching spacer type.

Referring to FIG. 7, the spacer 706 has a delta of 0f, where the n-type transistor and the p-type transistor of the corresponding standard cell have no quantifiable difference. As such, the transistor ratio of p-type transistors to n-type transistors is 1:1. In this regard, the spacer 706 can be denoted as the base case. The spacer 702 has a delta of +2f, where the n-type transistor has two more semiconductor fins than the p-type transistor in the corresponding standard cell for a lower transistor ratio than the transistor ratio corresponding to the spacer 706. According to some implementations, the delta increases positively (e.g., +3f, +4f, +5f) when the transistor ratio continues to decrease (e.g., an increasing number of semiconductor fins to form the n-type transistor compared to the p-type transistor for a greater transistor sizing of n-type transistors). The spacer 704 has a delta of +1f to denote that the n-type transistor has one more semiconductor fin than the p-type transistor. Conversely, the spacer 708 has a delta of −1f to denote that the p-type transistor has one more semiconductor fin than the n-type transistor.

Similarly, the spacer 710 has a delta of −2f to denote that the p-type transistor has two more semiconductor fins than the n-type transistor to push the N-WELL notch toward the n-type portion of the standard cell. In this regard, the delta increases negatively (e.g., −3f, −4f, −5f) when the transistor ratio continues to increase (e.g., an increasing number of semiconductor fins to form the p-type transistor compared to the n-type transistor for a greater transistor sizing of p-type transistors). As such, the quantification of the different boundaries available increases the likelihood that spacers might match during placement and/or routing.

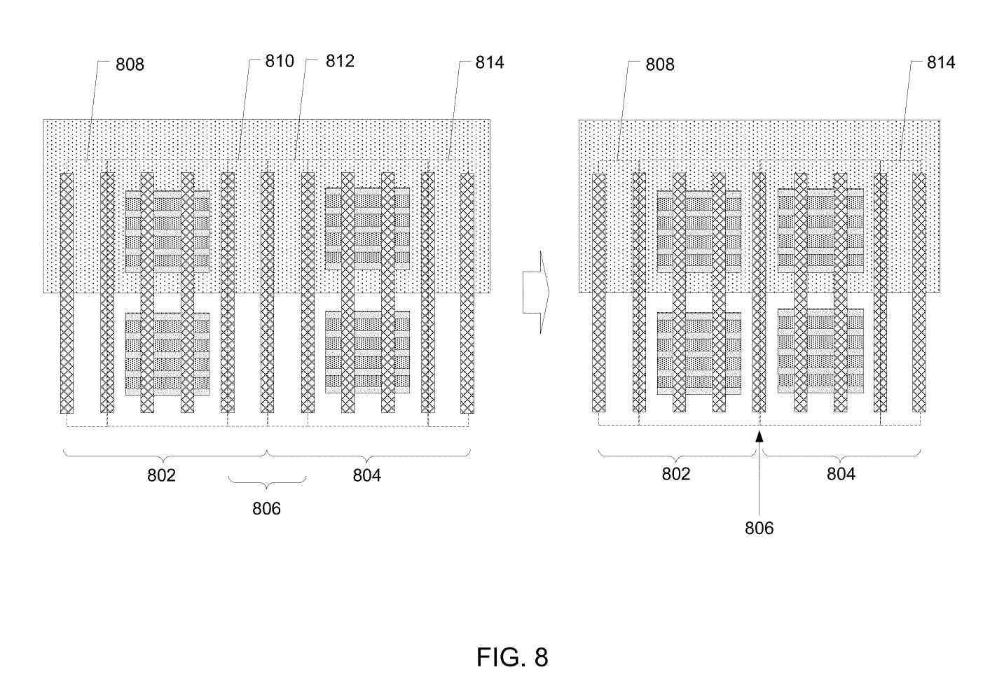

FIG. 8 illustrates a conceptual diagram of an optimization of adjacent standard cells 802 and 804 with corresponding spacers of a matching spacer type in accordance with one or more implementations. According to some implementations, the synthesis and placement of the standard cells 802 and 804 is performed with the spacers in place. Here, the standard cell 802 includes spacers 808 and 810, and the standard cell 804 includes spacers 812 and 814. When the optimization procedure is performed during the placement phase of the integrated circuit, the area utilized by the spacers 810 and 812 (e.g., area 806) can be recovered to reduce the overall size of the standard cells 802 and 804. This can be achieved when the two adjacent standard cells 802 and 804 have their corresponding spacers 808-714 of a same type located at a boundary between the adjacent standard cells (e.g., area 806 before optimization) are detected. Once detected, the spacer for each corresponding standard cell is removed, thus allowing the standard cells 802 and 804 to abut directly at the boundary (e.g., area 806 after optimization).

This area optimization allows optimal sizing flexibility, and does not cause a design-rule violation since the NWELL/NP/PP edges of the corresponding standard cells align properly. If such optimization is done at a later stage in the design process (e.g., during routing), the removed spacer area (e.g., area 806) can be filled with decoupling capacitance, which improves DC voltage drop (e.g., IR drop), and thereby increasing the integrated circuit's speed of operation (e.g., reducing propagation time across the circuit). In effect, the overall area of the standard cells 802 and 804 remains the same. Furthermore, the area reduction obtained during the placement stage reduces that average wire length required, thus reducing power and increasing the speed of operation. As a result of the spacer removal, the standard cell may be reconfigured to have only one spacer. Here, the standard cells 802 and 804 are each left with one spacer (e.g., spacers 808 and 814) on the non-contact sides. Alternatively, the standard cell may be reconfigured to have no spacers at all. As will be seen in FIG. 8, the standard cell can be left with no spacers when both adjoining sides had spacers of a same type with the adjacent spacer.

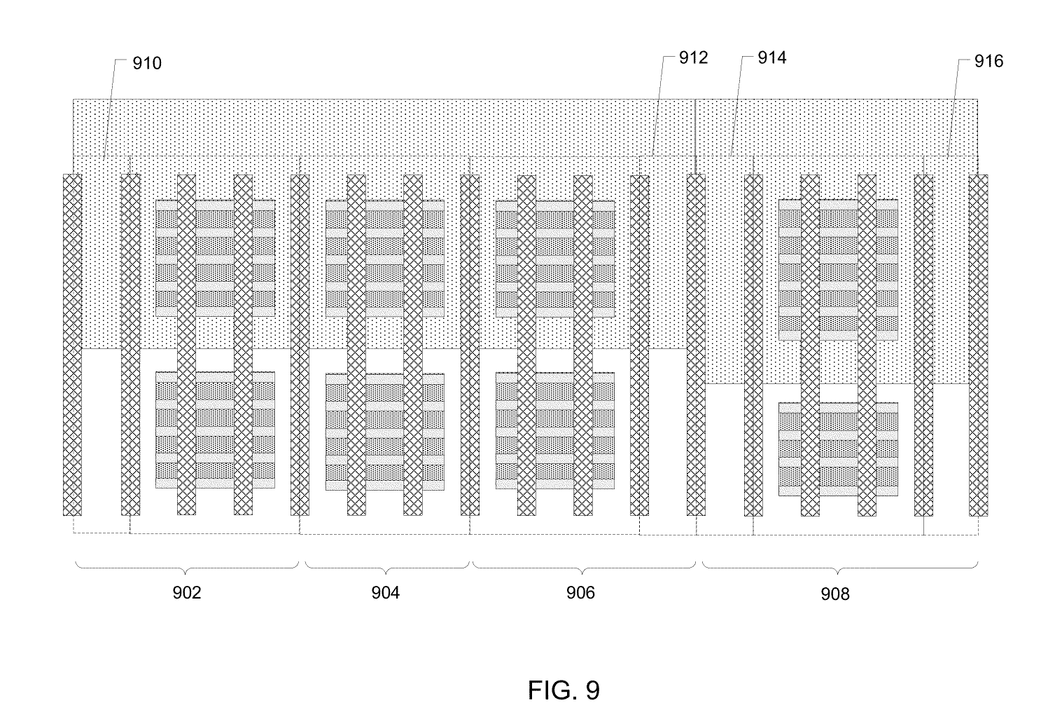

FIG. 9 illustrates a conceptual diagram of adjacent standard cells 902, 904, 906 and 908 with varying spacer types in accordance with one or more implementations. During the synthesis and placement of the standard cells 902, 904, 906 and 908, the standard cells are optimized to recover any area by determining whether any adjacent spacers are removable based on their spacer type. Here, the standard cell 902 includes a spacer 910, the standard cell 904 has no spacers, the standard cell 906 has a spacer 912, and the standard cell 908 has spacers 914 and 916 on each opposite side of the cell. The standard cells 902, 904 and 906 have common boundary types, and as a result are optimized to remove any corresponding spacers. Because the standard cells 902 and 904 share a common boundary type, the spacers corresponding to the standard cells 902 and 904 located at the boundary between the standard cells 902 and 904 are determined to have a matching spacer type (not shown). Hence, these spacers are removed and the standard cells 902 and 904 are placed to abut directly.

Similarly, the standard cells 904 and 906 share a common boundary type, and hence their corresponding spacers (not shown) have a matching spacer type. As a result, these spacers are also removed to allow the standard cells 904 and 906 to abut directly. In this regard, the standard cell 904 is left with no spacers after optimization, while the standard cells 902 and 906 are each left with one spacer. The reason that the standard cell 906 is left with one spacer is because the adjacent standard cell 908 has a different boundary type. Here, the standard cell 908 has a different transistor sizing than the standard cell 906, thus causing the edge position of the standard cell 908 to differ from the standard cell 906 by at least one semiconductor fin. In other words, the quantifiable difference can be shown as a delta of one (or −1f) since the p-type transistor sizing is greater than the n-type transistor sizing of the standard cell 908.

To accommodate the difference in edge positions, the spacers 912 and 914 can remain placed at the boundary between the standard cells 906 and 908. As such, the standard cell 908 also has a second spacer on the opposite side (or non-contact side) to remain with the spacers 914 and 916. According to some implementations, the standard cells shown in FIG. 9 can be placed, routed and optimized as other implementations or configurations than shown, and are not limited to the implementations, examples, and configurations of FIG. 9.

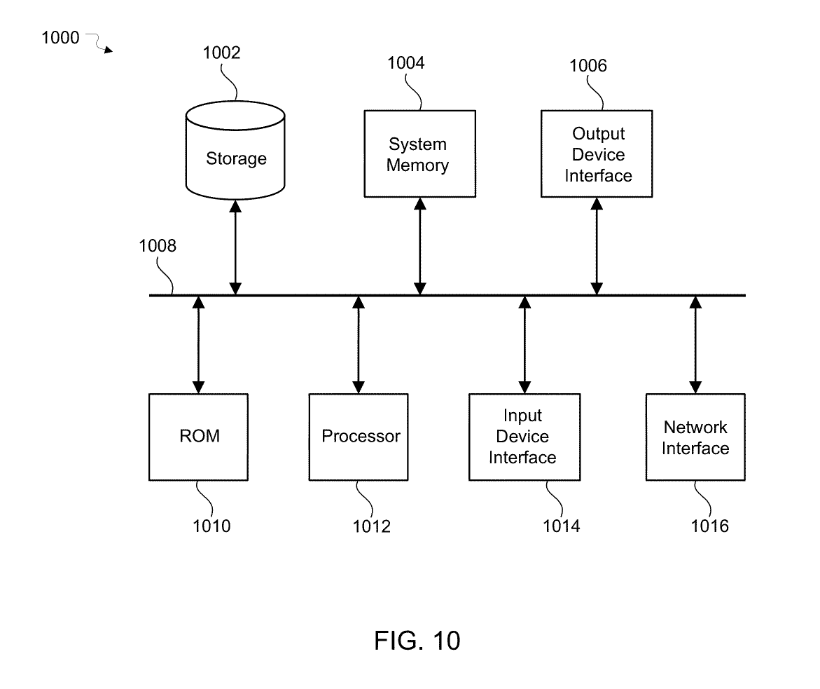

FIG. 10 conceptually illustrates an electronic system 1000 in accordance with one or more implementations. The electronic system 1000 includes a bus 1008, processing unit(s) 1012, a system memory 1004, a read-only memory (ROM) 1010, a permanent storage device 1002, an input device interface 1014, an output device interface 1006, and a network interface 1016, or subsets and variations thereof. As such, the method of forming an integrated circuit using the standard cell library 150 (FIG. 1) having area reconfigurable cells in order to optimize area dynamically in the integrated circuit can be implemented using processor-executable instructions that are stored on a computer-readable storage medium, such as the permanent storage device 1002, to be read from memory for execution by the processing unit 1012. In addition, the standard cell library 150 can be stored as processor-executable instructions on the computer-readable storage medium for execution by the processing unit 1012.

The bus 1008 collectively represents all system, peripheral, and chipset buses that communicatively connect the numerous internal devices of electronic system 1000. In one or more implementations, the bus 1008 communicatively connects the processing unit(s) 1012 with the ROM 1010, the system memory 1004, and the permanent storage device 1002. From these various memory units, the processing unit(s) 1012 retrieves instructions to execute and data to process in order to execute the processes of the subject disclosure. The processing unit(s) can be a single processor or a multi-core processor in different implementations.

The ROM 1010 stores static data and instructions that are needed by the processing unit(s) 1012 and other modules of the electronic system. The permanent storage device 1002, on the other hand, is a read-and-write memory device. This device is a non-volatile memory unit that stores instructions and data even when the electronic system 1000 is off. One or more implementations of the subject disclosure use a mass-storage device (such as a magnetic or optical disk and its corresponding disk drive) as the permanent storage device 1002.

Other implementations use a removable storage device (such as a floppy disk, flash drive, and its corresponding disk drive) as the permanent storage device 1002. Like the permanent storage device 1002, the system memory 1004 is a read-and-write memory device. However, unlike the storage device 1002, the system memory 1004 is a volatile read-and-write memory, such as random access memory. System memory 1004 stores any of the instructions and data that the processing unit(s) 1012 needs at runtime. In one or more implementations, the processes of the subject disclosure are stored in the system memory 1004, permanent storage device 1002, and/or ROM 1010. From these various memory units, the processing unit(s) 1012 retrieves instructions to execute and data to process in order to execute the processes of one or more implementations.

Bus 1008 also connects to input and output device interfaces 1014 and 1006. The input device interface 1014 enables a user to communicate information and select commands to the electronic system. Input devices used with the input device interface 1014 include, for example, alphanumeric keyboards and pointing devices (also called “cursor control devices”). Output device interface 1006 enables, for example, the display of images generated by the electronic system 1000. Output devices used with the output device interface 1006 include, for example, printers and display devices, such as a liquid crystal display (LCD), a light emitting diode (LED) display, an organic light emitting diode (OLED) display, a flexible display, a flat panel display, a solid state display, a projector, or any other device for outputting information. One or more implementations may include devices that function as both input and output devices, such as a touchscreen. In these implementations, feedback provided to the user can be any form of sensory feedback, such as visual feedback, auditory feedback, or tactile feedback; and input from the user can be received in any form, including acoustic, speech, or tactile input.

Finally, as shown in FIG. 10, the bus 1008 also couples the electronic system 1000 to a network (not shown) through the network interface 1016. In this manner, the computer can be a part of a network of computers (such as a local area network (“LAN”), a wide area network (“WAN”), or an Intranet, or a network of networks, such as the Internet. Any or all components of the electronic system 1000 can be used in conjunction with the subject disclosure.

According to some implementations, a computer program product for forming an integrated circuit using the area reconfigurable standard cell library 150 is provided. The computer program product comprising a non-transitory computer-readable storage medium (e.g., permanent storage device 1002) includes processor-executable instructions to cause a computer (e.g., processing unit 1012) to perform operations. The operations may include placing standard cells of the area reconfigurable standard cell library 150 on a circuit layout. Each of the standard cells has a boundary type and includes a body having a first pair of opposite sides and a second pair of opposite sides orthogonal to the first pair of opposite sides and a spacer located adjacent to each of the first pair of opposite sides of the body. The spacer has a spacer type that corresponds to the boundary type of the standard cell. The operations also may include that for each pair of adjacent standard cells, determining whether spacers located at a boundary between the pair of adjacent standard cells have matching spacer types. The operations also may include removing the spacers from the boundary between the pair of adjacent standard cells when the spacers are determined to have matching spacer types.

The processor-executable instructions can also cause the processing unit 1012 to detect a spacer type of each spacer located between the pair of adjacent standard cells, and also compare the spacer type of each spacer to determine a match. The processor-executable instructions can also cause the processing unit 1012 to evaluate an edge position of each spacer to determine a quantifiable difference based on a number of semiconductor fins. The processor-executable instructions can also cause the processing unit 1012 to abut the pair of adjacent standard cells directly with one another when the spacers having matching spacer types are removed from respective ones of the pair of adjacent standard cells. The processor-executable instructions can also cause the processing unit 1012 to place decoupling capacitors on the circuit layout at the boundary between the pair of adjacent standard cells.

Many of the above-described features and applications may be implemented as software processes that are specified as a set of instructions recorded on a computer readable storage medium (alternatively referred to as computer-readable media, machine-readable media, or machine-readable storage media). When these instructions are executed by one or more processing unit(s) (e.g., one or more processors, cores of processors, or other processing units), they cause the processing unit(s) to perform the actions indicated in the instructions. Examples of computer readable media include, but are not limited to, RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic and/or solid state hard drives, ultra density optical discs, any other optical or magnetic media, and floppy disks. In one or more implementations, the computer readable media does not include carrier waves and electronic signals passing wirelessly or over wired connections, or any other ephemeral signals. For example, the computer readable media may be entirely restricted to tangible, physical objects that store information in a form that is readable by a computer. In one or more implementations, the computer readable media is non-transitory computer readable media, computer readable storage media, or non-transitory computer readable storage media.

In one or more implementations, a computer program product (also known as a program, software, software application, script, or code) can be written in any form of programming language, including compiled or interpreted languages, declarative or procedural languages, and it can be deployed in any form, including as a stand alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

While the above discussion primarily refers to microprocessor or multi-core processors that execute software, one or more implementations are performed by one or more integrated circuits, such as application specific integrated circuits (ASICs) or field programmable gate arrays (FPGAs). In one or more implementations, such integrated circuits execute instructions that are stored on the circuit itself.

Those of skill in the art would appreciate that the various illustrative blocks, modules, elements, components, methods, and algorithms described herein may be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

It is understood that any specific order or hierarchy of blocks in the processes disclosed is an illustration of example approaches. Based upon design preferences, it is understood that the specific order or hierarchy of blocks in the processes may be rearranged, or that all illustrated blocks be performed. Any of the blocks may be performed simultaneously. In one or more implementations, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

As used in this specification and any claims of this application, the terms “base station”, “receiver”, “computer”, “server”, “processor”, and “memory” all refer to electronic or other technological devices. These terms exclude people or groups of people. For the purposes of the specification, the terms “display” or “displaying” means displaying on an electronic device.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

A phrase such as “an aspect” does not imply that such aspect is essential to the subject technology or that such aspect applies to all configurations of the subject technology. A disclosure relating to an aspect may apply to all configurations, or one or more configurations. An aspect may provide one or more examples of the disclosure. A phrase such as an “aspect” may refer to one or more aspects and vice versa. A phrase such as an “implementation” does not imply that such implementation is essential to the subject technology or that such implementation applies to all configurations of the subject technology. A disclosure relating to an implementation may apply to all implementations, or one or more implementations. An implementation may provide one or more examples of the disclosure. A phrase such an “implementation” may refer to one or more implementations and vice versa. A phrase such as a “configuration” does not imply that such configuration is essential to the subject technology or that such configuration applies to all configurations of the subject technology. A disclosure relating to a configuration may apply to all configurations, or one or more configurations. A configuration may provide one or more examples of the disclosure. A phrase such as a “configuration” may refer to one or more configurations and vice versa.

Any implementation described herein as an “example” is not necessarily to be construed as preferred or advantageous over other implementations. Furthermore, to the extent that the term “include,” “have,” or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. An integrated circuit using area reconfigurable cells of a standard cell library, the integrated circuit comprising:
a plurality of standard cells placed adjacent with one another in rows and columns, each of the plurality of standard cells having a boundary type, each of the plurality of standard cells comprising:
a body having a first pair of opposite sides and a second pair of opposite sides orthogonal to the first pair of opposite sides; and
a spacer located adjacent to each of the first pair of opposite sides of the body, the spacer having a spacer type that corresponds to the boundary type of the standard cell,
wherein the spacer is removable from the standard cell when the spacer has a spacer type that matches another spacer of an adjacent standard cell.

2. The integrated circuit of claim 1, wherein spacers located at a boundary between adjacent standard cells are removed when each of the spacers are determined to have a matching spacer type.

3. The integrated circuit of claim 2, wherein the adjacent standard cells are configured to abut directly with one another when the spacers with the matching spacer type are removed.

4. The integrated circuit of claim 3, wherein the adjacent standard cells have an area that is decreased proportionate to removed spacers.

5. The integrated circuit of claim 1, wherein the integrated circuit includes decoupling capacitors placed in between adjacent standard cells after spacers located between the adjacent standard cells are removed from respective ones of the adjacent standard cells.

6. The integrated circuit of claim 1, wherein the boundary type corresponds to an edge position of the standard cell, wherein the edge position is defined by a transistor sizing of the standard cell.

7. The integrated circuit of claim 6, wherein the plurality of standard cells comprises fin-shaped field-effect-transistors (finFETs), and wherein the edge position is quantified based on a number of semiconductor fins.

8. The integrated circuit of claim 7, wherein each of the plurality of standard cells comprises a p-type transistor and an n-type transistor.

9. A method of forming an integrated circuit using a standard cell library, comprising:
placing a plurality of standard cells of a standard cell library on a circuit layout, each of the plurality of standard cells having a boundary type and comprising a body having a first pair of opposite sides and a second pair of opposite sides orthogonal to the first pair of opposite sides and a spacer located adjacent to each of the first pair of opposite sides of the body, the spacer having a spacer type that corresponds to the boundary type of the standard cell;
for each pair of adjacent standard cells, determining whether spacers located at a boundary between the pair of adjacent standard cells have matching spacer types; and
removing the spacers from the boundary between the pair of adjacent standard cells when the spacers are determined to have matching spacer types.

10. The method of claim 9, wherein the determining comprises determining whether a pair of adjacent standard cells have edge positions that align.

11. The method of claim 9, wherein the determining comprises detecting a spacer type of each spacer located between a pair of adjacent standard cells.

12. The method of claim 11, wherein detecting the spacer type comprises comparing the spacer type of each spacer to determine a match.

13. The method of claim 12, wherein the plurality of standard cells include fin-shaped field-effect-transistors (finFETs), and wherein the determining comprises evaluating an edge position of each spacer to determine a quantifiable difference based on a number of semiconductor fins.

14. The method of claim 11, further comprising abutting the pair of adjacent standard cells directly with one another when the spacers having matching spacer types are removed from respective ones of the pair of adjacent standard cells.

15. The method of claim 11, further comprising placing decoupling capacitors on the circuit layout at the boundary between the pair of adjacent standard cells.

16. A computer program product for forming an integrated circuit using a standard cell library, the computer program product comprising a non-transitory computer-readable storage medium comprising processor-executable instructions to cause a computer to perform operations comprising:
placing a plurality of standard cells of a standard cell library on a circuit layout, each of the plurality of standard cells having a boundary type and comprising a body having a first pair of opposite sides and a second pair of opposite sides orthogonal to the first pair of opposite sides and a spacer located adjacent to each of the first pair of opposite sides of the body, the spacer having a spacer type that corresponds to the boundary type of the standard cell;
for each pair of adjacent standard cells, determining whether spacers located at a boundary between the pair of adjacent standard cells have matching spacer types; and
removing the spacers from the boundary between the pair of adjacent standard cells when the spacers are determined to have matching spacer types.

17. The computer program product of claim 16, wherein the determining comprises detecting a spacer type of each spacer located between the pair of adjacent standard cells, and wherein detecting the spacer type comprises comparing the spacer type of each spacer to determine a match.

18. The computer program product of claim 16, wherein the plurality of standard cells include fin-shaped field-effect-transistors (finFETs), and wherein the determining comprises evaluating an edge position of each spacer to determine a quantifiable difference based on a number of semiconductor fins.

19. The computer program product of claim 16, wherein the operations further comprise abutting the pair of adjacent standard cells directly with one another when the spacers having matching spacer types are removed from respective ones of the pair of adjacent standard cells.

20. The computer program product of claim 16, wherein the operations further comprise placing decoupling capacitors on the circuit layout at the boundary between the pair of adjacent standard cells.
